(19) United States
(12) Patent Application Publication
(10) Pub. No.: US 2004/0187777 A1
(43) Pub. Date: Sep. 30, 2004

(54) CVD apparatus

(75) Inventors: Yoshihiko Okamoto, Hyogo (JP); Kazuo Kobayashi, Hyogo (JP); Masao Togawa, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/648,541

(22) Filed: Aug. 27, 2003

(30) Foreign Application Priority Data
Mar. 24, 2003 (JP) 2003-079956(P)

(51) Int. Cl. C23C 16/00

(52) U.S. Cl. 118/715

(57) ABSTRACT

A CVD apparatus includes a plurality of first gas pipes connected to a gas mixing port and a plurality of gas vaporizers, respectively, to guide TEB, TEPO and TEOS from an appropriate gas vaporizer to the mixing port. The CVD apparatus also includes a plurality of second pipes connecting a plurality of liquid source origins with the plurality of gas vaporizers, respectively. Respective plurality of first gas pipes and respective plurality of second pipes corresponding to the plurality of first gas pipes constitute pipes of one line. In the comparison of a plurality of pipe lines, the length of the plurality of pipe lines is substantially equal to each other. Accordingly, a CVD apparatus that can easily deposit a desired CVD film is provided.

### BACKGROUND OF THE INVENTION

1. Field of the Invention

The present invention relates to a CVD (Chemical Vapor Deposition) apparatus used in fabrication of semiconductor devices.

2. Description of the Background Art

Conventionally known is a CVD apparatus using gas for deposition, i.e. gas of evaporated liquid source, under the state where the interior of the chamber is decompressed or reduced in pressure. In such a CVD apparatus, each of a plurality of gas vaporizers producing a plurality of types of gases constituting the deposition gas is connected through a plurality of pipes with a gas mixer provided in the neighborhood of a chamber in which an object to be processed is mounted.

In such a conventional CVD apparatus, the time required for the gas to arrive at the chamber differs between the plurality of types of gases due to the different length of the plurality of pipes. As a result, when any of the plurality of gases take a long time to arrive at the chamber, the gas(es) having a delay time is(are) liquefied again. This will offer difficulty in the deposition of a desired CVD film.

For example, there is a CVD apparatus depositing a CVD-BPSG (Boro-Phospho-Silicate Glass) film using deposition gas composed of a plurality of types of gases corresponding to evaporated TEOS (Tetra Ethyl Ortho Silicate) solution, TEPO (Tri Ethyl Phosphate Oxide: (C₂H₅O)₃P═O) solution, and TEB (Tri Ethyl Borate: (C₂H₅O)₃B) solution and also O₃ gas. This CVD apparatus must have the deposition gas, other vaporized gas, and the O₃ gas all introduced into the chamber at the same time.

However, all the plurality of types of gases cannot be introduced into the chamber at the same timing since there is difference in the length of each of the plurality of gas pipes. The gas that is introduced into the chamber at a later timing among the plurality of gases may attain a liquefied state.

There is known a CVD apparatus having O₃ gas which is an example of unreaction suppression gas introduced into the chamber to inhibit unreactant deposition gas from arriving at the object to be processed in the chamber before the flow of deposition gas is stabilized when CVD commences.

In such a CVD apparatus, there may be the case where the O₃ gas is not introduced into the chamber before the unreactant deposition gas arrives, depending upon the connecting position and length of the pipe through which O₃ is supplied as well as the connecting position and length of the pipe through which deposition gas is supplied. In this case, the deposition gas in an unreacted state will arrive at the chamber to come into contact with the object to be processed, resulting in a contaminant adhering to the object. Thus, there is a problem that a desired CVD film cannot be deposited.

There may be considered an approach of controlling the sequence of the input timing of a plurality of types of gases into the chamber of a CVD apparatus based on a program produced to control the input sequence of the plurality of types of gases into the chamber.

However, producing a program that optimizes the input timing of a plurality of types of gases is extremely time consuming. Considerable time is required to identify the length of each of the plurality of pipes, to identify the actual period of time of film deposition, and to repair (maintenance) the fabrication apparatus as a result of intentional generation of a fault. Reduction in the required time thereof is a great issue in the present field of art.

Thus, it was difficult to deposit a desired CVD film in the above-described conventional CVD apparatus. The need arises to provide a method of readily depositing a desired CVD film.

### SUMMARY OF THE INVENTION

An object of the present invention is to provide a CVD apparatus that can readily deposit a desired CVD film.

According to an aspect of the present invention, a CVD apparatus includes a chamber in which an object to be processed is mounted, a gas outlet to discharge into the chamber deposition gas to deposit a CVD film on an object to be processed, and a gas mixer connected to the gas outlet, and into which a plurality of types of gases are introduced and mixed to generate deposition gas.

The CVD apparatus also includes a plurality of gas vaporizers configured based on the usage of a plurality of gas vaporizers, each gas vaporizer evaporating liquid source gas to generate one of the plurality of types of gases, and a plurality of source gas origins configured based on the usage of a plurality of liquid source gas origins in which liquid source gas to be supplied to a gas vaporizer is stored.

The CVD apparatus also includes a plurality of gas pipes configured based on the usage of a plurality of gas pipes, connected to the gas mixer and respective plurality of gas vaporizers to guide any of the plurality of types of gases from a gas vaporizer to the gas mixer, and a plurality of source gas pipes connecting respective plurality of liquid source gas origins and respective plurality of gas vaporizers.

The pipe of one line is configured with a gas pipe and a source gas pipe corresponding to that gas pipe. In the comparison of a plurality of pipe lines, the length of the plurality of pipe lines is substantially identical to each other.

By the above-described configuration, the time required for gas to be guided to the gas mixer from a gas vaporizer is substantially identical to each other for the plurality of types of gases. This is advantageous in that liquefaction of gas having a later arriving time among the plurality of types of gases is suppressed. As a result, deposition of a desired CVD film is facilitated.

According to another aspect of the present invention, a CVD apparatus includes a chamber in which an object to be processed is mounted, and a gas outlet to discharge into the chamber deposition gas to deposit a CVD film on the object to be processed. The CVD apparatus also includes a gas mixer into which a plurality of types of gases are introduced and mixed to generate deposition gas, and a deposition gas channel guiding deposition gas from the gas mixer to the gas outlet. The CVD apparatus also includes an unreaction suppression gas pipe connected to the deposition gas channel to guide unreaction suppression gas into the deposition gas channel. The unreaction suppression gas is used to suppress deposition gas from being discharged from the gas outlet in an unreacted state.

By the above-described configuration, the event of unreaction suppression gas being introduced into the chamber before the arrival of deposition gas can be maintained. This suppresses the deposition gas from arriving at the object to be processed in an unreacted state. As a result, adherence of a contaminant to the object to be processed caused by unreactant deposition gas can be suppressed. Therefore, deposition of a desired CVD film is facilitated.

According to a further aspect of the present invention, a CVD apparatus includes a chamber in which an object to be processed is mounted, and a gas outlet discharging into the chamber deposition gas to deposit a CVD film on the object to be processed. The CVD apparatus also includes a gas mixer connected to the gas outlet to have a plurality of types of gases introduced and mixed to generate deposition gas, and a gas vaporizer in which liquid source gas is evaporated to generate any of the plurality of types of gases. The CVD apparatus includes a gas pipe connected to the gas mixer and the gas vaporizer, and through which any of the plurality of types of gases is guided, and a gas flow rate control mechanism provided at the gas pipe to control the gas flow rate of any of the plurality of types of gases so that deposition gas is gradually introduced into the chamber.

In general, introduction of a plurality of types of gases corresponding to evaporation of liquid source gas to the chamber in a stabilized state is relatively time consuming, depending on the performance of the gas vaporizer. The pressure in the chamber may change suddenly. By providing the above-described gas flow rate control mechanism, sudden variation in the pressure in the chamber caused by rapid change in the flow rate of deposition gas introduced into the chamber can be suppressed. As a result, adherence of a contaminant generated in the chamber to an object to be processed can be suppressed. Accordingly, deposition of a desired CVD film is facilitated.

According to still another aspect of the present invention, a CVD apparatus includes a chamber in which an object to be processed is mounted, and a gas outlet discharging into the chamber deposition gas to deposit a CVD film on the object to be processed. The CVD apparatus includes a gas mixer connected to the gas outlet to have a plurality of types of gases introduced and mixed to generate deposition gas. The CVD apparatus includes a gas vaporizer generating any of the plurality of types of gases by evaporating liquid source gas, and a liquid source gas origin supplying liquid source gas to the gas vaporizer. The CVD apparatus includes a connection pipe connecting the gas vaporizer with the liquid source gas origin, and a gas flow rate control mechanism provided at the connection pipe to control the flow rate of liquid source gas.

Each of the liquid source gas, liquid source gas origin, connection pipe, and gas vaporizer is provided in plurality corresponding to the plurality of types of gases. The gas flow rate control mechanism controls the flow out timing of liquid source gas from each of the plurality of liquid source gas origins so that the input timing of each of the plurality of types of gases into the gas mixer is substantially identical.

By virtue of the above-described structure, the time required for each of the plurality of types of liquid source gases being evaporated and input into the gas mixer is substantially identical between the plurality of types of liquid source gases. This suppresses liquefaction of the gas having a later arriving time among the plurality of types of gases. As a result, deposition of a desired CVD film is facilitated.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram to describe the structure and feature of a CVD apparatus according to a first embodiment.

FIGS. 2-4 are diagrams to describe the feature of a gas flow rate regulating valve.

FIG. 5 is a diagram to describe the advantage achieved by the feature of a gas flow rate regulating valve.

FIG. 6 is a diagram to describe a structure and feature of a CVD apparatus according to a second embodiment.

FIG. 7 is a diagram to describe the relationship between the pressure in a processing chamber and the elapsed time from initiating supply of liquid source gas when a gas slow start mechanism is not used.

FIG. 8 is a diagram to describe the relationship between the flow rate of liquid source gas and the elapsed time from initiating supply of liquid source gas when a gas slow start mechanism is not used.

FIG. 9 is a diagram to describe the relationship between the delay time of arrival of liquid source gas into a processing chamber and the pressure in the processing chamber when a gas slow start mechanism is not employed.

FIG. 10 is a diagram to describe the relationship between the pressure in a processing chamber and the elapsed time from initiating supply of liquid source gas when a gas slow start mechanism is employed.

FIG. 11 is a diagram to describe the relationship between the flow rate of liquid source gas and the elapsed time from initiating supply of liquid source gas when a gas slow start mechanism is employed.

### DESCRIPTION OF THE PREFERRED EMBODIMENTS

Embodiments of a CVD apparatus of the present invention will be described hereinafter with reference to the drawings.

First Embodiment

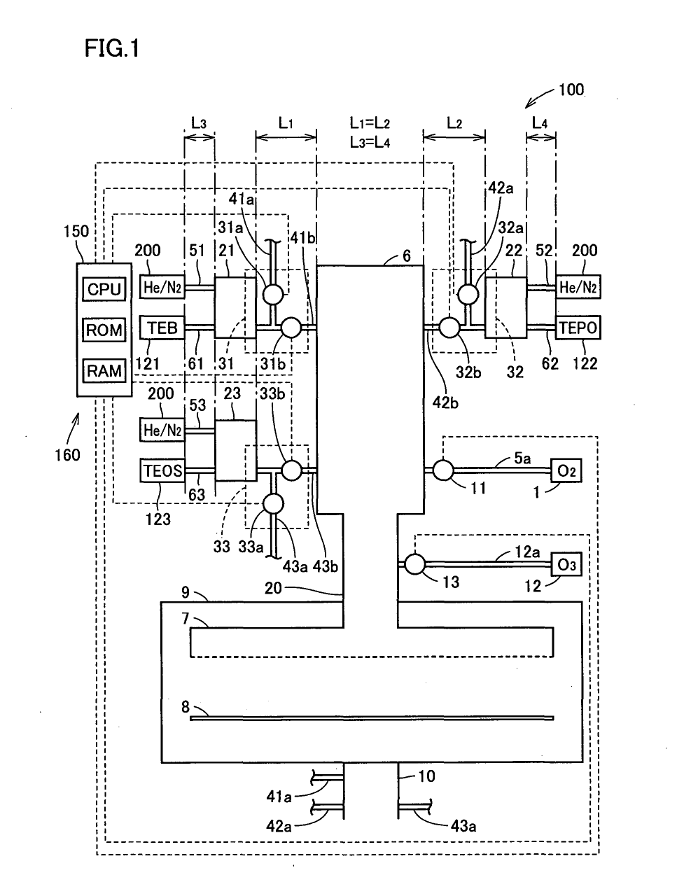

A CVD apparatus according to a first embodiment of the present invention will be described hereinafter with reference to FIGS. 1-5.

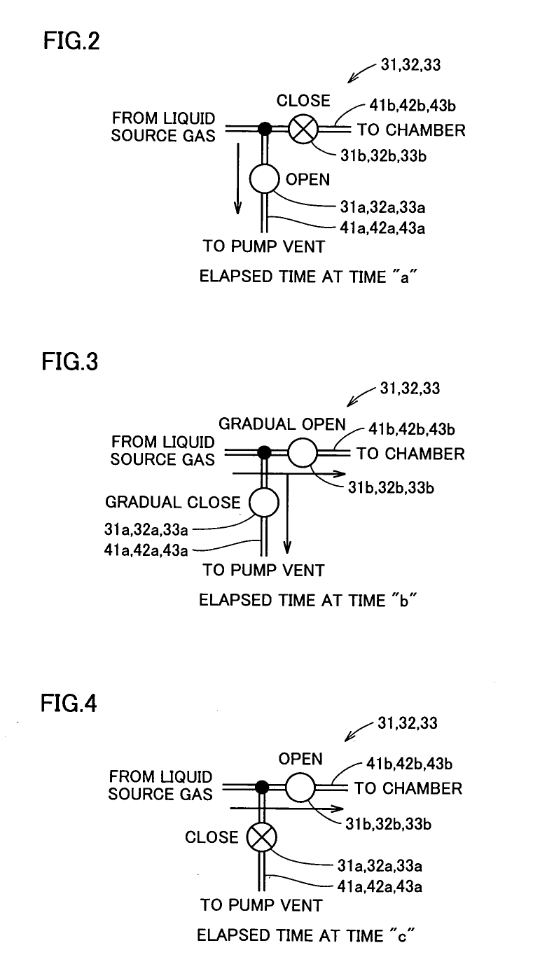

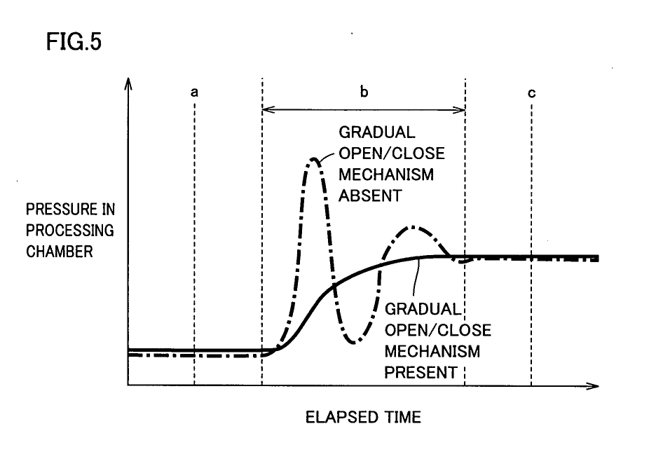

FIG. 1 shows a CVD apparatus of the first embodiment. FIGS. 2-4 are diagrams to describe the operation of a gradual OPEN/CLOSE mechanism of a gas flow rate regulating valve of the present embodiment. FIG. 5 represents the relationship between the pressure in a processing chamber and the elapsed time from initiating supply of liquid source gas. FIG. 5 allows comparison between a comparative CVD apparatus absent of a gradual OPEN/CLOSE mechanism and a CVD apparatus of the present embodiment with a gradual OPEN/CLOSE mechanism.

A CVD apparatus 100 of the present embodiment includes a processing chamber 9 in which is mounted a wafer 8 or an object having a film formed on wafer 8, which is an object to be processed. CVD apparatus 100 also includes a gas shower head 7 functioning as a gas outlet to discharge into processing chamber 9 mixture gas of TEB, TEPO and TEOS as the deposition gas to deposit a CVD film on wafer 8 or an object having a film formed on wafer 8.

CVD apparatus 100 further includes a gas mixing port 6 as a gas mixer connected to gas shower head 7. TEB, TEPO and TEOS identified as a plurality of types of gases are introduced and mixed at gas mixing port 6 to generate deposition gas. CVD apparatus 100 also includes gas vaporizers 21, 22 and 23 in which TEB, TEPO and TEOS identified as liquid source gases, respectively, are evaporated to generate gaseous TEB, TEPO and TEOS, respectively.

CVD apparatus 100 includes liquid source gas origins 121, 122 and 123 storing TEB, TEPO and TEOS, respectively, identified as the liquid source gas to be supplied to gas vaporizers 21, 22 and 23, respectively. CVD apparatus 100 also includes gas pipes 41b, 42b and 43b connected to gas mixing port 6 and corresponding gas vaporizers 21, 22 and 23, respectively, to guide TEB, TEPO and TEOS from gas vaporizers 21, 22 and 23, respectively, to gas mixing port 6.

CVD apparatus 100 also includes source gas pipes 61, 62 and 63, establishing connection between corresponding liquid source gas origins 121, 122 and 123 and plurality of gas vaporizers 21, 22 and 23, respectively. The pipe of one line is formed of gas pipes 41b, 42b and 43b and corresponding source gas pipes 61, 62 and 63, respectively. In the comparison of the plurality of pipe lines, the length of each of the plurality of pipe lines is substantially identical to each other.

By virtue of the above-described structure, the time required for gas to be guided from respective liquid source gas origins 121, 122 and 123 to gas mixing port 6 is substantially identical in the comparison of the gases of TEB, TEPO and TEOS as the plurality of types of gases. Therefore, liquefaction of the gas having a later arriving time among the gases of TEB, TEPO and TEOS can be suppressed. As a result, deposition of a desired CVD film is facilitated.

Each of the plurality of gas pipes 41b, 42b and 43b is substantially provided with only gas flow rate regulating valves 31b, 32b and 33b, respectively. Each of gas vaporizers 21, 22 and 23 is provided in the proximity of gas mixing port 6.

By the above-described structure, the length of each of the plurality of gas pipes 41b, 42b and 43b can be minimized. This allows reduction in the difference between the time required for gas to be guided to gas mixing port 6 from respective gas vaporizers 21, 22 and 23 in the comparison of the gases of TEB, TEPO and TEOS identified as the plurality of types of gases. Thus, deposition of a desired CVD film is facilitated.

Flow acceleration gas pipes 51, 52 and 53 are connected to gas vaporizers 21, 22 and 23, respectively. Through each of flow acceleration gas pipes 51, 52 and 53 is guided inert gas (He/H₂) identified as flow acceleration gas to accelerate the flow of respective TEB, TEPO and TEOS identified as a plurality of types of gases in gas pipes 41b, 42b and 43b, respectively. Each of TEB, TEPO and TEOS is introduced into gas mixing port 6 in a state mixed with the inert gas (He/H₂). Each of acceleration gas pipes 51, 52 and 53 is connected to an inert gas origin 200. TEB, TEPO and TEOS identified as liquid source gases are stored in liquid source gas origins 121, 122 and 123, respectively. TEB, TEPO and TEOS are introduced into gas vaporizers 21, 22 and 23, respectively, via gas pipes 61, 62 and 63, respectively.

By virtue of the above-described structure, the time required for gas to be guided to gas mixing port 6 from respective gas vaporizers 21, 22 and 23 become substantially identical in the comparison between TEB, TEPO and TEOS identified as the plurality of types of gases including inert gas (He/H₂). Thus, deposition of a desired CVD film is facilitated.

CVD apparatus 100 further includes a deposition gas channel 20 to guide TEB, TEPO and TEOS as the deposition gas from gas mixing port 6 to gas shower head 7. CVD apparatus 100 further includes an unreaction suppression gas pipe 12a connected to deposition gas channel 20 for guiding O₃ gas into deposition gas channel 20. The O₃ gas is identified as an unreaction suppression gas to suppress TEB, TEPO and TEOS from being discharged out from gas shower head 7 in an unreacted state.

By virtue of the above-described structure, the event of the O gas identified as unreaction suppression gas being introduced into processing chamber 9 prior to TEB, TEPO and TEOS identified as the deposition gas can be maintained. This prevents TEB, TEPO and TEOS from reaching wafer 8 or the like that is the object to be processed in an unreacted state. This suppresses adhesion of a contaminant to wafer 8 or the like caused by TEB, TEPO and TEOS in an unreacted state. Thus, deposition of a desired CVD film is facilitated.

CVD apparatus 100 is also provided with a flow rate control valve 13 adjusting the flow rate of O₃ gas identified as unreaction suppression gas in the neighborhood of the connection between deposition gas channel 20 and unreaction suppression gas pipe 12a.

By virtue of the above-described structure, the introduction timing of O₃ gas into processing chamber 9 can be controlled easier. Thus, deposition of a desired CVD film is facilitated. The O₃ gas and O₂ gas are supplied from an O₃ gas supply origin 12 and an O₂ gas supply origin 1, respectively, to unreaction suppression gas pipe 12a and gas pipe 5a.

CVD apparatus 100 includes gas pipes 41b, 42b and 43b establishing connection between corresponding gas vaporizers 21, 22, 23 and gas mixing port 6 for guiding TEB,TEPO and TEOS, respectively. CVD apparatus 100 includes air valves 31a, 31b, 32a, 32b, 33a and 33b provided corresponding to gas pipes 41b, 42b and 43b, respectively. Air valves 31a, 31b, 32a, 32b, 33a and 33b constitute a portion of a gas flow rate control mechanism 160 controlling the flow rate of respective TEB, TEPO and TEOS identified as a plurality of types of gases so that each of TEB, TEPO and TEOS is gradually introduced into processing chamber 9 as deposition gas.

Introduction of TEB, TEPO and TEOS into processing chamber 9 in a stabilized state as a plurality of types of gases corresponding to evaporated liquid source gases of TEB, TEPO and TEOS is relatively time consuming, depending on the performance of gas mixing port 6. Therefore, the pressure in processing chamber 9 may change suddenly. In view of this problem, air valves 31a, 31b, 32a, 32b, 33a and 33b configuring gas flow rate control mechanism 160 are provided.

Accordingly, the problem of sudden change in the pressure in processing chamber 9 due to sudden change in the flow rate of TEB, TEPO and TEOS identified as the deposition gas introduced into processing chamber 9 can be suppressed. As a result, adhesion of a contaminant generated in processing chamber 9 to wafer 8 or the like can be suppressed. Thus, deposition of a desired CVD film is facilitated.

Gas vaporizers 21, 22 and 23 are connected to flow acceleration gas pipes 51, 52 and 53, respectively, through which inert gas (He and/or H₂) identified as the flow acceleration gas to accelerate flow of TEB, TEPO and TEOS in gas pipes 41b, 42b and 43b, respectively, is guided. Mixture gas having inert gas (He and/or H₂) mixed with respective TEB, TEPO and TEOS is introduced into gas mixing port 6.

By virtue of the above-described structure, the flow of each of TEB, TEPO and TEOS identified as the plurality of types of gases is facilitated by means of inert gas (He and/or H₂). Therefore, the introduction pressure of the gas introduced into processing chamber 9 can be adjusted easily. Thus, deposition of a desired CVD film is facilitated.

Gas flow rate control mechanism 160 includes gas pipes 41b, 42b and 43b establishing connection between corresponding gas vaporizers 21, 22, 23 and gas mixing port 6 for guiding TEB, TEPO and TEOS from gas vaporizers 21, 22 and 23, respectively, to gas mixing port 6.

Gas flow rate control mechanism 160 includes air valves 31b, 32b and 33b as the first gas flow rate regulating valve adjusting the flow rate of each of TEB, TEPO and TEOS in gas pipes 41b, 42b and 43b, respectively. One of air valves 31b, 32b and 33b is provided corresponding to corresponding one of gas pipes 41b, 42b and 43b.

Gas flow rate control mechanism 160 includes discharge gas pipes 41a, 42a and 43a connected to gas pipes 41b, 42b and 43b, respectively, to output the TEB, TEPO and TEOS in gas pipes 41b, 42b and 43b, respectively, from processing chamber 9. Each of discharge gas pipes 41a, 42a and 43a is connected to a discharge gas pipe 10 to discharge the gas in processing chamber 9 out from processing chamber 9. Gas flow rate control mechanism 160 includes air valves 31a, 32a and 33a provided at discharge gas pipes 41a, 42a and 43a, respectively, identified as the second gas flow rate regulating valve to adjust the flow rate of TEB, TEPO and TEOS in discharge gas pipes 41a, 42a and 43a, respectively.

By virtue of the above-described structure, the introduction timing of TEB, TEPO and TEOS identified as the deposition gas introduced into processing chamber 9 can be adjusted without having to use a gas flow rate regulating valve of a complicated structure. Thus, deposition of a desired CVD film can be facilitated.

Gas flow rate control mechanism 160 includes a RAM (Read Only Memory) in which a program is stored, a CPU (Central Processing Unit), and a RAM (Random Access Memory), functioning as first flow rate control means for controlling the flow rate of each of TEB, TEPO and TEOS identified as the deposition gas passing through air valves 31b, 32b and 33b, respectively, by controlling independently the amount of passage of air valves 31b, 32b, and 33b.

Gas flow rate control mechanism 160 includes means functioning as second flow rate control means for controlling the flow rate of each of TEB, TEPO and TEOS passing through air valves 31a, 32a and 33a, respectively, by controlling independently the amount of passage of air valves 31a, 32a and 33a. The means includes a ROM in which a program is stored, a CPU and an RAM. The first and second flow rate control means are configured as the internal elements of computer 150.

By virtue of the above-described structure, the timing of introducing deposition gas into processing chamber 9 can be controlled automatically. As a result, deposition of a desired CVD film is facilitated.

Gas flow rate control mechanism 160 increases the flow of gas passing through respective air valves 31b, 32b and 33b by operating the first flow rate control means in association with reducing the flow of gas passing through respective air valves 31a, 32a and 33a by operating the second flow rate control means.

By virtue of the above-described structure, deposition gas can be introduced into processing chamber 9 without an abrupt change in pressure in processing chamber 9. As a result, deposition of a desired CVD fi can be facilitated.

The function of the CVD apparatus of the present embodiment will be described hereinafter.

In the CVD apparatus of FIG. 1, TEOS, TEPO, TEB, O₃ and O₂, as well as He and/or H₂ are supplied into processing chamber 9 via gas mixing port 6. Introduction of O₂ gas among the above-cited gases into gas mixing port 6 depends upon the opening/closing control of an air valve 11 through computer 150 in gas flow control mechanism 160. Introduction of O₃ gas among the above-cited gases into deposition gas channel 20 depends on the opening/closing control of an air valve 13 through computer 150 in gas flow rate control mechanism 160.

TEB, TEPO and TEOS that are liquid source gases supplied from liquid source gas origins 121, 122 and 123 are evaporated at gas vaporizers 21, 22 and 23, respectively. Then, each of the plurality of types of liquid source gases has the flow rate adjusted by gas flow rate control mechanism 160 to be introduced into gas mixing port 6 through gas pipes 41b, 42b and 43b, respectively.

Only the O₃ gas among the above-cited gases passes through gas pipe 12a to be introduced into gas shower head 7 via air valve 13. In other words, only the O₃ gas is introduced into gas shower head 7 from a site closer than the sites of other gases. The open/close control of air valves 13 and 11 is conducted by computer 150.

Air valves 31a, 31b, 32a, 32b, 33a and 33b and gas vaporizers 21, 22 and 23 are installed in the proximity of gas mixing port 6. Accordingly, the pipe distance between each of gas vaporizers 21, 22 and 23 and gas mixing port 6 is substantially equal to each other.

As a result, deposition gas of the required amount can be properly supplied to gas shower head 7 precisely, when required. Accordingly, an operator to control the supplying status of deposition gas, required from the standpoint of detecting error in the state of the gas supplied to gas shower head 7, is dispensable.

It is to be noted that O₃ gas is introduced into gas shower head 7 from a site closer than the site of other gases. Therefore, deposition gas is introduced in an O₃ gas-rich state in the gas mixture in gas shower head 7. Therefore, deposition gas reaches wafer 8 without liquefaction in gas shower head 7. Accordingly, deposition of a desired CVD film can be conducted constantly in a stable manner.

The gradual OPEN/CLOSE mechanism identified as gas flow rate control mechanism 160 will be described with reference to FIGS. 2-4. The gradual OPEN/CLOSE mechanism allows gas to be introduced gradually into gas mixing port 6 from gas vaporizers 21, 22 and 23 by controlling the OPEN/CLOSE operation of air valves 31a, 31b, 32a, 32b, 33a and 33b. Specifically, the gradual OPEN/CLOSE mechanism refers to the mechanism of controlling independently the amount of passage of each of air valves 31a, 31b, 32a, 32b, 33a and 33b.

By gradually introducing gas from gas vaporizers 21, 22 and 23 into gas mixing port 6 by means of the gradual OPEN/CLOSE mechanism, a system is implemented that is dispensable of an operator to control the introducing state of gas into gas mixing port 6.

At a time “a” in FIG. 5, respective air valves 31b, 32b and 33b are closed whereas respective air valves 31a, 32a and 33a are open, as shown in FIG. 2. Accordingly, the plurality of types of gases will not flow towards processing chamber 9, and will be output from pump discharge pipe 10. As a result, the plurality of types of gases are not introduced into gas mixing port 6. At this stage, stabilization of the flow rate of deposition gas is intended.

During the period of time “b” in FIG. 5, air valves 31b, 32b and 33b on the part of pipes 41b 42b and 43b, respectively, to conduct the flow of the plurality of types of gases to processing chamber 9 is gradually opened (gradual OPEN) while air valves 31a, 32a and 33a on the part of pipes 41a, 42a and 43a, respectively, to conduct the flow of the plurality of types of gases to pump discharge pipe 10 is closed (gradual CLOSE). At this stage, the plurality of types of gases flow towards respective sides of processing chamber 9 and pump discharge pipe 10.

At a time “c” in FIG. 5, each of air valves 31b, 32b and 33b is completely opened, and each of air valves 31a, 32a and 33a is completely closed, as shown in FIG. 4. Accordingly, deposition gas will no longer be discharged from pump discharge pipe 10, and all the deposition gas flows to gas mixing port 6. Thus, the switching operation of the flowing direction of deposition gas ends.

As shown in FIG. 5, the pressure in processing chamber 9 is constant in a substantially vacuum state at time “a”, and gradually increases during the period of time “b”. The pressure in processing chamber 9 will not suddenly change, and increases extremely smoothly. At time “c”, the pressure within processing chamber 9 attains a constant level since introduction of deposition gas into processing chamber 9 is completed.

By the above procedure, the flow rate of deposition gas to be introduced into processing chamber 9 during the period of time “b” can be increased stably. This means that TEB, TEPO and TEOS identified as the plurality of types of deposition gases can all be introduced into processing chamber 9 at a stable flow rate under the desired mixed state. Thus, the step of depositing a desired CVD film can be conducted in a constant stable state.

Second Embodiment

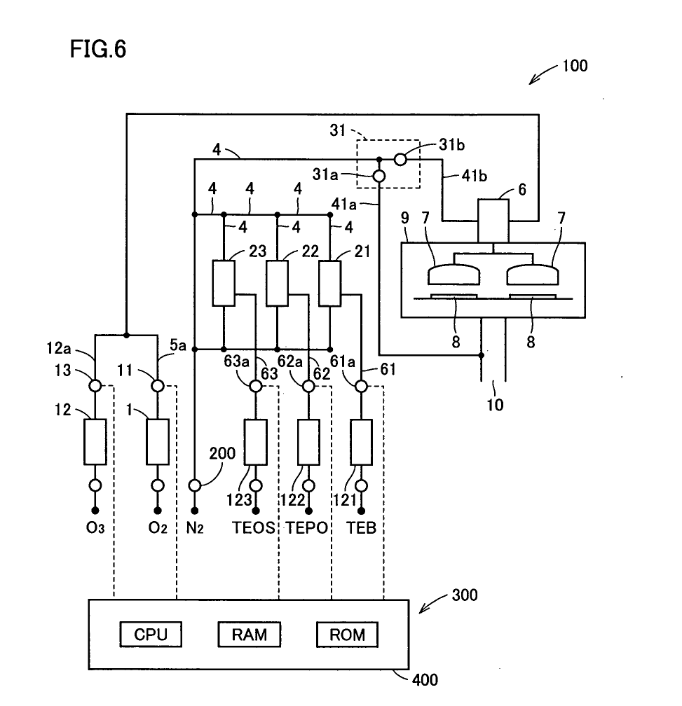

A CVD apparatus according to a second embodiment of the present invention will be described hereinafter with reference to FIGS. 6-11.

CVD apparatus 100 of the present embodiment has a structure and function set forth below, as shown in FIG. 6. Components in CVD apparatus 100 of the second embodiment with reference numbers identical to those of the CVD apparatus of the first embodiment have the same function as those of the CVD apparatus of the first embodiment. It is to be noted that CVD apparatus 100 of the second embodiment is absent of a flow rate control mechanism provided corresponding to each of gas vaporizers 21, 22 and 23, as in the previous CVD apparatus 100 of the first embodiment. Specifically, CVD apparatus 100 of the second embodiment has flow rate regulating valves 31a and 31b identified as flow rate adjustment mechanism discharge gas pipe 41a provided at gas pipe 4 through which the plurality of gases from gas vaporizers 21, 22 and 23 flow together.

CVD apparatus 100 includes a processing chamber 9 in which is mounted a wafer 8 or an object having a film formed on wafer 8, which is an object to be processed. CVD apparatus 100 also includes a gas shower head 7 functioning as a gas outlet to discharge into processing chamber 9 mixture gas of TEB, TEPO and TEOS as the deposition gas to deposit a CVD film on wafer 8 or an object having a film formed on wafer 8.

CVD apparatus 100 further includes a gas mixing port 6 as a gas mixer connected to gas shower head 7. TEB, TEPO and TEOS identified as a plurality of types of gases are introduced and mixed at gas mixing port 6 to generate deposition gas. CVD apparatus 100 also includes gas vaporizers 21, 22 and 23 in which TEB, TEPO and TEOS identified as liquid source gases, respectively, are evaporated to generate gaseous TEB, TEPO and TEOS, respectively.

CVD apparatus 100 includes liquid source gas origins 121, 122 and 123 storing TEB, TEPO and TEOS, respectively, identified as the liquid source gas to be supplied to gas vaporizers 21, 22 and 23, respectively. CVD apparatus 100 includes connection pipes 61, 62 and 63 establishing connection between gas vaporizers 21, 22 and 23, respectively and liquid source gas origins 121, 122 and 123, respectively. Connection pipes 61, 62 and 63 are provided with a gas flow rate control mechanism 300 controlling the flow rate of each of TEB, TEPO and TEOS.

TEB, TEPO and TEOS identified as the aforementioned liquid source gases, liquid source gas origins 121, 122 and 123, and connection pipes 61, 62 and 63 are provided corresponding to TEB, TEPO and TEOS identified as the plurality of gases, respectively.

Gas flow rate control mechanism 300 controls the flowing timing of TEB, TEPO and TEOS out from liquid source gas origins 121, 122, and 123, respectively, by means of fluid valves 61a, 62a, and 63a, respectively, provided corresponding to connection pipes 61, 62, and 63, respectively. Accordingly, the introduction timing of each of TEB, TEPO and TEOS into gas mixing port 6 is substantially identical to each other.

By virtue of the above-described structure, the time required for the gas to arrive at gas mixing port 6 from liquid source gas origins 121, 122 and 123 is substantially identical between TEB, TEPO and TEOS that are a plurality of types of liquid source gases. Therefore, liquefaction of the gas having a later arrival time among the plurality of types of gases of TEB, TEPO and TEOS is suppressed. Thus, deposition of a desired CVD film is facilitated.

Gas flow rate control mechanism 300 includes a sequence controller 400 controlling the introduction timing of deposition gas into processing chamber 9. CVD apparatus 100 includes fluid valves 61a, 62a and 63a provided corresponding to pipes 61, 62 and 63, respectively, to open/close in response to an instruction signal from sequence controller 400.

Sequence controller 400 includes a timer identified as clock means. The timer calculates a plurality of arriving times of each of TEB, TEPO and TEOS arriving at processing chamber 9 from liquid source gas origins 121, 122 and 123, respectively. The timer is configured with a CPU, a RAM, and a ROM.

Sequence controller 400 includes a CPU as calculation means for obtaining the difference between the arrival times of the plurality of types of liquid source gases based on the plurality of types of arriving times calculated by the timer. Sequence controller 400 includes instruction means for sequentially providing an instruction signal to each of fluid valves 61a, 62a and 63a in accordance with the difference between the arriving times calculated by the CPU. Each of fluid valves 61a, 62a and 63a receives an instruction signal to open/close so as to conduct the flow of TEB, TEPO and TEOS at the timing specified by the instruction signal.

By virtue of the above-described structure, the introduction timing of deposition gas into processing chamber 9 can be adjusted. Therefore, sudden change in pressure in processing chamber 9 can be suppressed. Thus, deposition of a desired CVD film is facilitated.

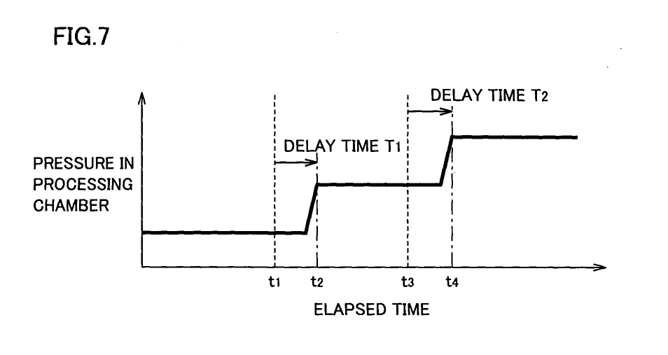

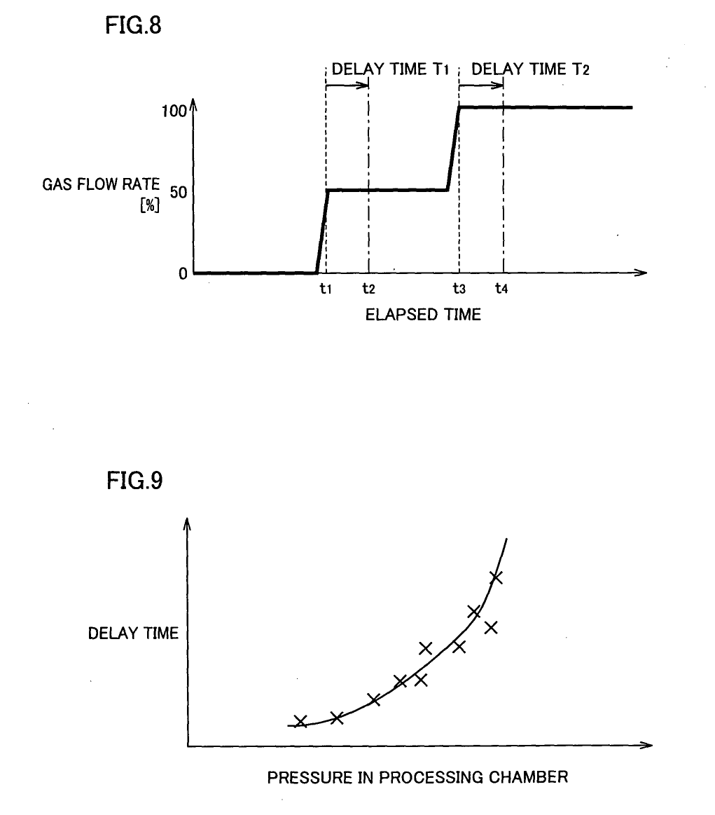

FIG. 7 represents the relationship between the pressure in processing chamber 9 and the elapsed time from initiating supply of liquid source gas at liquid source gas origins 121, 122 and 123 in a comparative CVD apparatus. FIG. 8 represents the relationship between the flow rate of liquid source gas supplied from a liquid source gas origin and the elapsed time of initiating, supply of liquid source gas in a comparative CVD apparatus.

It is appreciated from FIGS. 7 and 8 that there are delays T₁ (t₂-t₁) and T₂ (t₄-t₃) in the rising timing of the pressure in processing chamber 9 with respect to the rising timing of the flow rate of gas introduced into processing chamber 9. The delay times T₁ and T₂ are caused by the difference in the length of the pipes from each of liquid source gas origins 121, 122 and 123 to processing chamber 9. Referring to FIG. 6, it is particularly noted that there is difference in length between pipes 4, i.e. the length in the pipe path from each of gas vaporizers 21, 22 and 23 to gas mixing port 6.

Therefore, the time required for each of TEB, TEPO and TEOS to arrive at processing chamber 9 from liquid gas source origins 121, 122 and 123 respectively, will differ from each other. However, by conducting the prestage process that will be described afterwards using a gas slow(defer) start mechanism in the CVD apparatus 100 of the second embodiment, the arriving time of each of TEB, TEPO and TEOS at processing chamber 9 can be optimized.

FIG. 9 represents the relationship between the pressure in processing chamber 9 and the delay time of any one of TEB, TEPO and TEOS in a comparative CVD apparatus. This relationship is based on calculation conducted by sequence controller 400.

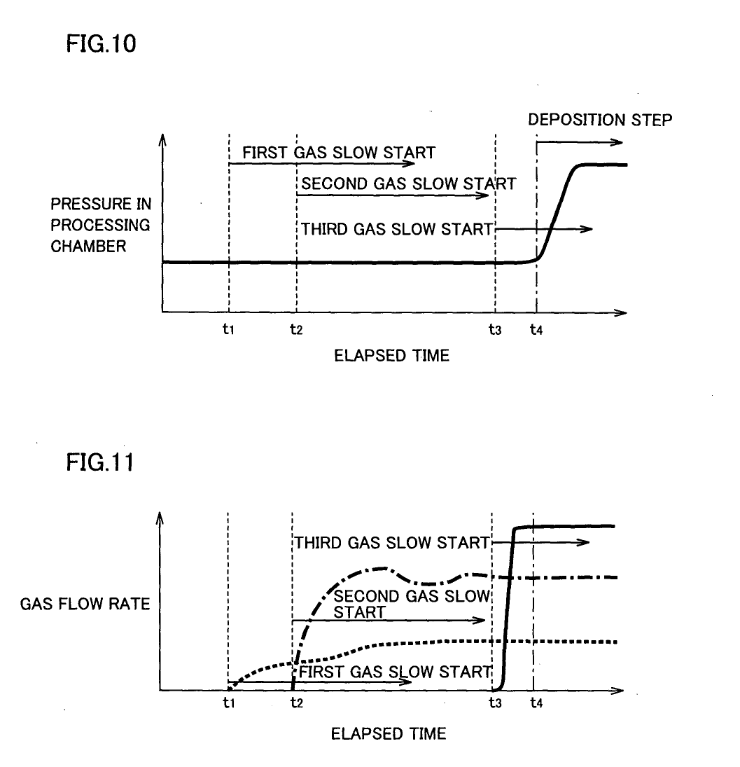

FIG. 10 represents the relationship between the pressure in processing chamber 9 and the elapsed time from initiating supply of liquid source gas in the case where a gas slow(defer) start mechanism is employed. FIG. 11 represents the relationship between the flow rate of gas supplied from liquid source gas origins 121, 122 and 123 and the elapsed time from initiating supply of liquid source gas in the case where a gas slow(defer) start mechanism is employed.

It is appreciated from FIGS. 10 and 11 that the delay time of gas associated with pressure increase in processing chamber 9 is controlled by adjusting the initiation time of gas supply into processing chamber 9 based on the relationship among TEB, TEPO and TEOS in the CVD apparatus of the second embodiment employing a slow(defer) start mechanism.

Adjustment of the delay time by means of the slow start mechanism in the second embodiment is executed by procedures set forth below.

First, each of TEB, TEPO and TEOS identified as a plurality of types of deposition gases is introduced individually into processing chamber 9 attaining a state of reduced pressure. At this stage, each of TEB, TEPO and TEOS individually flows through pipe 4. However, the arriving time of each of TEB, TEPO and TEOS at processing chamber 9 will differ depending upon the gas flow rate, the length of pipe 4, and the pressure in processing chamber 9.

The relationship between the arriving time of each of TEB, TEPO and TEOS at processing chamber 9 and the gas flow rate is automatically monitored over several times by means of sequence controller 400. Sequence controller 400 of CVD apparatus 100 of the second embodiment can automatically control the flow rate of liquid source gas and the pressure in processing chamber 9.

Sequence controller 400 stores in a RAM the data of the delay time of each of TEB, TEPO and TEOS obtained through automatic monitoring shown in FIG. 9. The CPU of sequence controller 400 calculates the actual time of deposition gas arriving at processing chamber 9 based on the stored delay time data in order to determine the output timing of a supply initiation instruction signal for each of TEB, TEPO and TEOS.

For example, sequence controller 400 executes the control of sequentially altering the degree of opening up each of fluid valves 61a, 62a and 63a to 0%, 50% and 100% while monitoring the pressure in processing chamber 9. Accordingly, sequence controller 4 stores the data of the relationship between the degree of opening of each of fluid valves 61a, 62a and 63a and the pressure in processing chamber 9. Sequence controller 300 also counts the time of a, b and c described in the previous first embodiment with respect to each pressure value while sequentially altering the pressure value in processing chamber 9 to 1→10→100→300→500→650 Torr. Then, information of the measured times of a, b and c is stored in the RAM of sequence controller 400. Sequence controller 400 also calculates the delay time of deposition gases TEB, TEPO and TEOS with respect to the first one of TEB, TEPO and TEOS arriving at processing chamber 9 based on the information of time a, b and c stored in the RAM.

Then, sequence controller 400 outputs a supply initiation instruction signal for each liquid source gas so that the plurality of types of gases flow into gas mixing port 6 substantially at the same time based on the information of the required time of TEB, TEPO and TEOS evaporated as deposition gases to arrive at processing chamber 9 and the delay time information, as shown in FIG. 9.

In CVD apparatus 100 of the second embodiment, the delay time caused by difference in the length of pipe 4 is detected. A supply initiation instruction signal corresponding to the delay time is output to the liquid source gas valve through which flows the liquid source gas having a delay time with respect to the liquid source gas identified as arriving earliest at processing chamber 9.

This means that initiation of the supply of liquid source gas with the delay time is conducted at a stage earlier than that of the gas potentially expected to arrive earliest at processing chamber 9. Therefore, all the deposition gases can be introduced at substantially the same timing into processing chamber 9 in CVD apparatus 100 of the second embodiment.

As a result, the step of depositing a CVD film can always be executed under the state where the desired deposition gas is supplied into the chamber. Furthermore, deposition of a CVD film is facilitated since only the operation to designate supply initiation of liquid source gas is required in the operation of supplying deposition gas.

Although an apparatus with the combination of the features of the CVD apparatuses of the first and second embodiments is not described here, one such apparatus can offer advantages achieved through respective features.

The above-described CVD apparatuses are configured so that the timing of introducing the plurality of types of deposition gases into processing chamber 9 is substantially identical. The timing can be set so that other gases are also introduced into the chamber at the same time as the deposition gases, i.e., all gases including deposition gases are introduced at the same time.

The mechanism employed in the gradual OPEN/CLOSE mechanism is not limited to air valve 11 shown in FIG. 1 of the first embodiment. Any mechanism can be employed for the gradual OPEN/CLOSE mechanism as long as the flow rate of deposition gas introduced into processing chamber 9 is gradually increased. Accordingly, advantages similar to those of the above-described CVD apparatus can be achieved.

The connection between a valve and control means is indicated in dotted lines in FIG. 1 of the first embodiment and FIG. 6 of the second embodiment. These dotted lines may correspond to electrical lines, or a route of signals over radio.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A CVD apparatus comprising:
a chamber in which an object to be processed is mounted;
a gas outlet discharging into said chamber deposition gas to deposit a CVD film on said object to be processed;
a gas mixer connected to said gas outlet, and having a plurality of types of gases introduced and mixed to generate said deposition gas;
a plurality of gas vaporizers, configured based on a usage of a plurality of gas vaporizers to evaporate liquid source gas and generate any of said plurality of types of gases;
a plurality of source gas origins, configured based on a usage of a plurality of liquid source gas origins in which is stored said liquid source gas to be supplied to said gas vaporizer;
a plurality of gas pipes connected to said gas mixer and respective plurality of gas vaporizers, configured based on a usage of a plurality of gas pipes to guide any of said plurality of types of gases from said gas vaporizer to said gas mixer; and
a plurality of source gas pipes connecting respective said plurality of liquid source gas origins and respective said plurality of gas vaporizers;
said gas pipe and said source gas pipe corresponding to said gas pipe constituting pipes of one line, and lengths of a plurality of pipe lines are substantially identical to each other in comparison of said plurality of pipe lines with each other.

2. The CVD apparatus according to claim 1, wherein
only a gas flow rate regulating valve is substantially provided at each of said plurality of gas pipes, and
said gas vaporizer is provided at a neighborhood of said gas mixer.

3. The CVD apparatus according to claim 1, wherein
each of said plurality of gas vaporizers is connected to a flow acceleration gas pipe through which is guided flow acceleration gas accelerating flow of said plurality of types of gases in said gas pipe, and
said plurality of types of gases are introduced into said mixer in a state where said flow acceleration gas is mixed.

4. A CVD apparatus comprising:
a chamber in which an object to be processed is mounted;
a gas outlet to discharge into said chamber deposition gas to deposit a CVD film on said object to be processed;
a gas mixer connected to said gas outlet, and having a plurality of types of gases introduced and mixed to generate said deposition gas;
a deposition gas channel guiding said deposition gas from said gas mixer to said gas outlet; and
an unreaction suppression gas pipe connected to said deposition gas channel to guide unreaction suppression gas into said deposition gas channel, said unreaction suppression gas suppressing said deposition gas from being discharged out from said gas outlet in an unreacted state.

5. The CVD apparatus according to claim 4, wherein a gas flow rate control valve adjusting a flow rate of said unreaction suppression gas is provided at a neighborhood of a connection between said deposition gas channel and said unreaction suppression gas pipe.

6. A CVD apparatus comprising:
a chamber in which an object to be processed is mounted;
a gas outlet discharging into said chamber deposition gas to deposit a CVD film on said object to be processed;
a gas mixer connected to said gas outlet, and having a plurality of types of gases introduced and mixed to generate said deposition gas;
a gas vaporizer evaporating liquid source gas to generate any of said plurality of types of gases;
a gas pipe connected to said gas mixer and said gas vaporizer to guide any of said plurality of types of gases; and
a gas flow rate control mechanism provided at said gas pipe to control a flow rate of any of said plurality of types of gases such that said deposition gas is gradually introduced into said chamber.

7. The CVD apparatus according to claim 6, wherein
said gas vaporizer is connected to a flow acceleration gas pipe through which is guided flow acceleration gas accelerating flow of said plurality of types of gases in said gas pipe, and
said plurality of types of gases are introduced into said mixer in a state where said flow acceleration gas is mixed.

8. The CVD apparatus according to claim 6, wherein said gas flow rate control mechanism comprises
a first gas flow rate regulating valve provided at said gas pipe to adjust a flow rate of gas in said gas pipe,
a discharge gas pipe connected to said gas pipe to guide gas in said gas pipe out from said chamber, and
a second gas flow rate regulating valve provided at said discharge gas pipe to adjust a flow rate of gas in said discharge gas pipe.

9. The CVD apparatus according to claim 8, wherein said gas flow rate control mechanism comprises
first flow rate control means for controlling a flow rate of gas passing through said first gas flow rate regulating valve by controlling a degree of opening up said first gas flow rate regulating valve, and
second flow rate control means for controlling a flow rate of gas passing through said second gas flow rate regulating valve by controlling a degree of opening up said second gas flow rate regulating valve.

10. The CVD apparatus according to claim 9, wherein said gas flow rate control mechanism operates said first flow rate control means to increase flow of gas passing through said first flow rate regulating valve while said second flow rate control means is operated to reduce flow of gas passing through said second flow rate regulating valve.

11. A CVD apparatus comprising:
a chamber in which an object to be processed is mounted;
a gas outlet to discharge into said chamber deposition gas to deposit a CVD film on said object to be processed;
a gas mixer connected to said gas outlet, and having a plurality of types of gases introduced and mixed to generate said deposition gas;
a gas vaporizer to evaporate liquid source gas to generate any of said plurality of types of gases;
a liquid source gas origin supplying said liquid source gas to said gas vaporizer;
a connection pipe connecting said gas vaporizer with said liquid source gas origin; and
a gas flow rate control mechanism provided at said connection pipe to control a flow rate of said liquid source gas,
said liquid source gas, said liquid source gas origin, said connection pipe, and said gas vaporizer are respectively provided in plurality, corresponding to respective said plurality of types of gases,
said gas flow rate control mechanism controlling a timing of output of said liquid source gas from respective said plurality of liquid source gas origins such that the timing of each of said plurality of types of gases being introduced into said gas mixer is substantially identical.

12. The CVD apparatus according to claim 11, wherein
said gas flow rate control mechanism comprises a sequence controller controlling a timing of introducing said deposition gas into said chamber,
a liquid source gas valve opening and closing in response to an instruction signal from said sequence controller is provided at each of said plurality of connection tubes,
said sequence controller comprises
clock means for calculating a plurality of arriving times required for each of said plurality of types of liquid source gases to arrive at said chamber from each of said plurality of types of liquid source gas origins,
calculation means for obtaining a difference in an arriving time of said plurality of types of liquid source gases based on said plurality of arriving times calculated by said clock means, and
instruction means for sequentially providing said instruction signal to each of said plurality of liquid source gas valves in accordance with the difference in the arriving time calculated by said calculation means,
each of a plurality of said liquid source gas valves receiving said instruction signal to open so as to conduct a flow of said liquid source gas at a timing specified by said instruction signal.
